(19) United States
(12) Patent Application Publication
(10) Pub. No.: US 2002/0094687 A1
(43) Pub. Date: Jul. 18, 2002

(54) Method of fabricating semiconductor device for preventing contaminating particle generation

(76) Inventors: Young-Goo Lee, Yongin-si (KR); Tae-Ryong Kim, Suwon-si (KR); Jin-Sung Kim, Suwon-si (KR); Jin-Joo Kim, Seoul (KR); Jung-Soo An, Yongin-si (KR); Jong-Kook Song, Suwon-si (KR)

Correspondence Address: VOLENTINE FRANCOS, P.L.L.C., Suite 150, 12200 Sunrise Valley Drive, Reston, VA, 20191, US

(21) Appl. No.: 10/029,147

(22) Filed: Dec. 28, 2001

(30) Foreign Application Priority Data
Jan. 15, 2001 (KR) 2001-2218

(51) Int. Cl. H01L 21/302

(52) U.S. Cl. 438/692

(57) ABSTRACT

A method of fabricating a semiconductor device to prevent contaminating particle formation. The method includes depositing a layer having a selected thickness on a wafer and then planarizing the deposited layer. A photoresist layer is then coated on the deposited layer. An edge portion of the coated photoresist layer is removed to thereby expose a dead zone region of the deposited layer, with the dead zone region corresponding to a portion of the initial deposited layer which is not removed during the planarization process. The exposed deposited layer of the dead zone region is then etched, and the photoresist layer remaining on the wafer is stripped to form the desired pattern.

### BACKGROUND OF THE INVENTION

1. Field of the Invention

The present invention relates to a method of fabricating a semiconductor device, and more specifically, to a fabrication method that is capable of preventing particle generation at a thick deposit layer remaining at a dead zone region corresponding to an edge of a wafer after a planarization process is performed.

2. Description of the Related Art

The elements of a semiconductor device are becoming more densely integrated with finer and finer patterns to improve the processing speed and other performance parameters. As a result, manufacturing processes and mass production techniques are becoming increasingly sophisticated in order to produce these finer, highly integrated patterns for the semiconductor devices.

One process among the many manufacturing process steps involves the intermediate planarization of the multiple layers comprising the semiconductor device. For example, a chemical mechanical polishing (CMP) process and a pad poly process make it possible to improve the flatness and uniformity of silicon oxide layers within the semiconductor device. However, these processes have some problems and drawbacks.

For example, the CMP process may cause fine scratches or generate particles that can degrade the performance or contaminate the device. The pad poly process may cause fluid particle contamination due to the employment of a sacrificial oxide etch process followed by the use of the poly pad.

The ability to control particle contamination during the manufacturing process is indispensable to ensure the proper functioning of the semiconductor devices, and to improve production yields. However, it is not always easy to determine the precise source of the particles.

In one particular case of particle contamination, it has been observed that particles are moved from an edge of a wafer toward a pattern on-the wafer. A main component of the particles is a silicon substance, such as,silicon (Si) or silicon dioxide (SiO₂). As can be expected, finding the source of the silicon-contamination is an extensive process and not easily deduced, given that many elements in the semiconductor field are comprised of silicon (Si) or SiO₂ type materials.

For example, the following elements are likely sources of Si or SiO₂ particle generation at an edge of a wafer: a quartz bath and a quartz robot arm used in a wet bath, a quartz tube and a quartz boat used in a diffusion process, a focus ring, a shadow ring and a shower head of silicon or quartz used in a dry etch process, and slurry used as a polishing source in a CMP process. Moreover, since the wafer itself is made of Si, SiO₂, SiN, etc., it may be also a source of particle contamination due to scratching or chipping.

The chemical mechanical polishing (CMP) process is widely used in the semiconductor manufacturing field for horizontally planarizing various kinds of layers, such as oxide layers, nitride layers, metal layers and the like, which are sequentially deposited on the semiconductor wafer to form the integrated circuits.

In a CMP process, a polishing support table is used for supporting and rotating a CMP pad positioned on the table. A wafer confronts the CMP pad, and is fixed and rotated by a carrier, which moves vertically to selectively contact the CMP pad, which CMP pad is also rotated at the same time by the table. A slurry mixture, which comprises a mixture of predetermined-types of chemicals and other ingredients, is provided at the-central point of the CMP pad, and then evenly distributed and coated on the upper surface of the CMP pad by the rotating force of the CMP pad. The semiconductor wafer attached to the wafer carrier selectively contacts the slurry covered CMP pad.

As a result of the relative rotation between the wafer and the CMP pad, and the slurry mixture on the surface of the CMP pad, both mechanical friction and chemical reactions take place, and the material comprising the layer to be polished is gradually removed from the surface of the wafer. As a result, a wafer is said to be planarized to a certain pre-set thickness on the surface of the wafer.

The film polished by the CMP process is generally deposited using a chemical vapor deposition (CVD) process. During the CVD process, a film having a desired thickness is grown by a chemical reaction on the surface of the wafer, except a rear portion of the wafer. A typical CVD process produces a film on the upper surface of the wafer only, while a Low Pressure CVD (LPCVD) process allows a film to be grown on both the upper and lower surfaces of the wafer.

Depending on the structure of the CVD apparatus, there may occur a phenomenon in which a film is grown at a dead zone region corresponding to an edge portion of the upper surface of the wafer, or at the lower surface of the wafer, and the grown film at the edge portion or lower surface of the wafer has a thickness different from that of the film formed on the upper surface of the wafer. In-order to prevent the film from growing on the lower surface, a flow of N₂ gas is generally applied to the lower surface of the wafer during the deposition process. However, such a preventive measure is not feasible for application at the upper surface of the wafer considering the structure of the CVD apparatus, and thus a film of non-uniform thickness is usually deposited at a dead zone region of the upper surface of the wafer.

FIGS. 1 to 3 are schematic views illustrating a conventional method for fabricating a semiconductor device. Referring to FIG. 1, after a film is deposited on a wafer 10, the deposited layer 20, such as an oxide layer, exhibits a tendency to have a higher growth rate at a dead zone region 24 (see FIG. 2) corresponding to an upper sidewall or edge portion of the wafer 10, due to the characteristics of the gas flow used to form the layer.

Thereafter, as shown in FIG. 2, a conventional CMP process is performed to planarize the deposited layer 20. Note that the planarized deposited layer 22 of the upper surface side has a uniform thickness extending nearly to the edge of the wafer, but the planarized deposited layer in the dead zone region 24, corresponding to the upper sidewall portion of the wafer 10, has a non-uniform thickness due to the inherent restrictions of the CMP process and the initial gas flow characteristics. As a result, the deposited layer on the upper side wall portion of the wafer 10 remains thicker relative to the planarized deposited layer 22 remaining on the upper surface of the wafer 10. Moreover, the slurries may accumulate at the dead zone region 24 and thus the probability of particle occurrence becomes higher. As can be seen, after the CMP process is completed, the difference in the thickness of the deposited layer 20 between the uniform planarized deposited layer 22 and the non-uniform portion at the dead zone region 24 is increased relative to the pre-planarized conditions.

Afterwards, in order to form a pattern on the planarized deposit layer, a photolithography process and a dry etch process are sequentially performed. In the general patterning process, an edge expose wafer (EEW) process is also performed to remove the deposited layer of the exposed sidewall of the wafer 10.

Referring to FIG. 3, since the deposited layer 20 in the dead zone region 24 was thicker than that of the planarized deposited layer 22, even after the CMP and etching processes, a residual oxide 26 still remains at the upper sidewall portion of the wafer 10. This is because the dry etch is performed with reference only to the thickness of the planarized deposited layer 22 formed on the upper surface of the wafer 10.

Moreover, a group of cone shaped particles 28 are generated at a boundary between the removed portion of the deposited layer and the remaining portion of the deposited layer at an edge of the upper surface of the wafer 10. The group of cone shaped particles 28 comprise a silicon substance, such as silicon (Si), silicon dioxide (SiO₂), or the like.

As the deposition of a layer and the-dry etch are repeated; the region comprising these cone shaped particles 28 becomes wider and wider. As a result, these particles generated at the dead zone region 24 move toward a pattern on the wafer during a wet etch process as indicated by the arrow in FIG. 3. In particular, this phenomenon frequently occurs in a wet etch process using an HF solution. For example, if a wet etch process using an HF solution is performed during a pretreatment process, many cone shaped particles 28 are generated at the dead zone region, which then separate from the boundary and are introduced into the pattern 20 along with the flow of the wet etch chemical, thereby contaminating the pattern. These cone shaped particles 28 can grow larger and may change into spherical particles during a subsequent film deposition process.

In view of the foregoing, it is necessary to continue the efforts to identify and remove sources of particle contamination.

### SUMMARY OF THE INVENTION

An object of the present invention is to provide a method of fabricating a semiconductor device that is capable of preventing particle generation and enhancing production yields by minimizing a thickness of a deposit layer remaining at a dead zone region corresponding to an edge of a wafer.

To achieve the above objects and other advantages, there is provided a method for fabricating a semiconductor device, including depositing a layer on a wafer and then planarizing the deposited layer. The resulting planarized layer has a uniform region of uniform thickness extending along a wafer surface and nearly to an edge of the wafer, and a non-uniform region of non-uniform thickness corresponding to the edge of the wafer. A photoresist layer is coated on the planarized layer, and then a portion of the coated photoresist layer corresponding to an edge region of the wafer is removed, thereby exposing at least the non-uniform region of the planarized layer. The exposed non-uniform region of the planarized layer is etched, and a remaining portion of the coated photoresist layer on the planarized layer is stripped, thereby forming a pattern layer comprising a portion of the uniform region of the planarized layer.

According to another aspect of the present invention, there is provided a method of fabricating a semiconductor device, including depositing a layer on a wafer, with the deposited layer having a uniform region of uniform thickness extending along a wafer surface and nearly to an edge of the wafer, and a non-uniform region of non-uniform thickness corresponding to the edge of the wafer. A photoresist layer is first coated on the deposited layer, and then a portion of the coated photoresist layer is removed, corresponding to an edge region of the wafer, thereby exposing at least the non-uniform region of the deposited layer. At least the exposed non-uniform region of the deposited layer is etched, and then the coated photoresist layer remaining on the wafer is stripped. The-uniform region of the deposited -layer is then planarized to thereby form a pattern layer.

In the present invention, a residual deposited layer remaining at the dead zone region of the wafer is removed prior to, or after, a planarization process is performed, resulting in a remarkable decrease in the occurrence of contaminating particles generated during the patterning processes.

### BRIEF DESCRIPTION OF THE DRAWINGS

The above objects and other advantages of the present invention will become more apparent by describing in detail the preferred embodiments thereof with reference to the accompanying drawings, in which:

FIGS. 1 to 3 are schematic views illustrating a conventional method for fabricating a semiconductor device;

FIGS. 4 to 7 are schematic views illustrating a method for fabricating a semiconductor device in accordance with an embodiment of the present invention;

FIGS. 8 to 11 are schematic views illustrating a method for fabricating a semiconductor device in accordance with another embodiment of the present invention; and

FIGS. 12A and 12B are particle maps of a wafer prepared in accordance with a process of the present invention, and a conventional process, respectively.

### DETAILED DESCRIPTION OF THE PREFERRED EMBODIMENTS

The present invention will now be described more fully with reference to the accompanying drawings, in which a preferred embodiment of the invention is shown. This invention may, however, be embodied in many different forms and should not be construed as being limited to the embodiments set forth herein. Rather, the embodiments are provided so that this disclosure will be thorough and complete, and will fully convey the concept of the invention to those skilled in the art. In the drawings, the thickness of a layer or region are exaggerated for clarity. It will also be understood that when a layer is referred to as being “on” another layer or substrate, it can be directly on the other layer or substrate, or intervening layers may also be present.

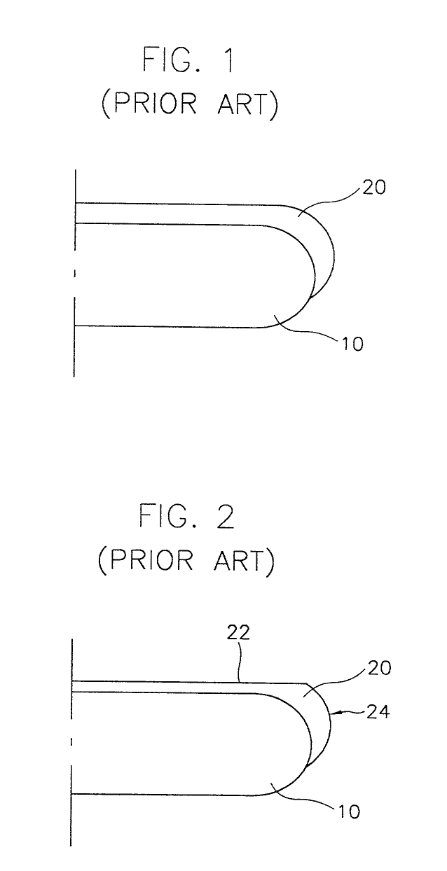

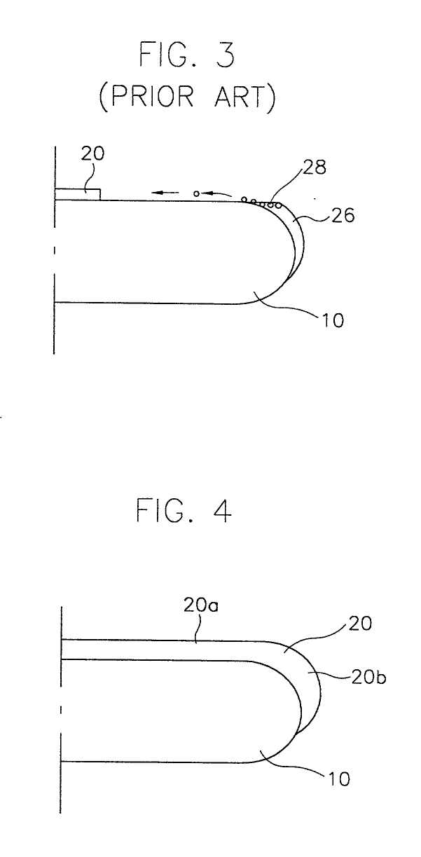

As described above with reference to FIGS. 1 to 3, the particle contamination during the CMP process originates because of a difference in the thickness between the deposited layer on the upper surface of the wafer 10, and the deposited layer of the upper sidewall of the wafer 10 after the CMP process is performed. Thus, to eliminate the contamination problem, the present invention is broadly directed to a method of removing the deposited layer at the upper sidewall region either prior to, or after the CMP process is performed.

FIGS. 4 to 7 are schematic views illustrating a method for fabricating a semiconductor device in accordance with an embodiment of the present invention, in which the deposited layer at the upper sidewall region is removed prior to performing the CMP planarization process.

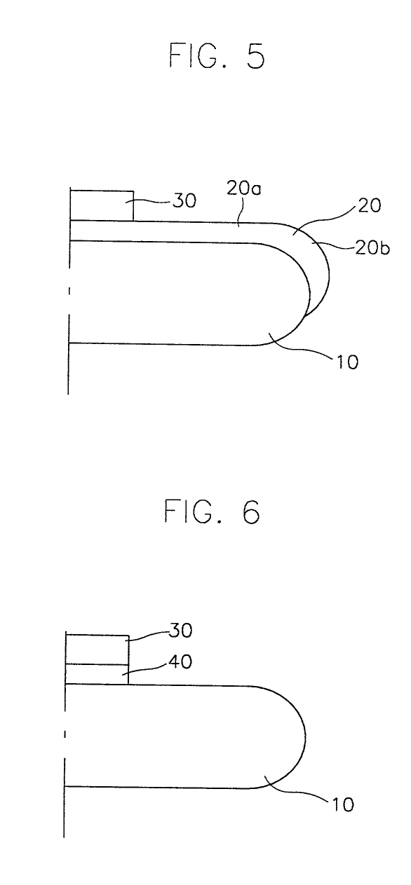

Referring to FIGS. 4 and 5, a deposited layer 20 is formed on a wafer 10. Note that the deposited layer 20 has a region of uniform thickness 20a extending along the wafer surface and nearly to the edge of the wafer 10, and a region 20b of non-uniform thickness corresponding to an upper sidewall or edge of the wafer 10. Thereafter, a photoresist film 30 is coated on the entire deposited layer 20 with a thickness in the range of approximately 5000-15000 Å. Afterwards, an edge portion of the photoresist film 30 is removed by an edge expose wafer (EEW) process, to thereby expose at least the edge portion of the deposited layer 20 (i.e., non-uniform region 20b) as shown in FIG. 5. As also shown in FIG. 5, depending on the desired pattern, a portion of the uniform region 20a may also be exposed when the photoresist film 30 is removed.

Referring to FIG. 6, any exposed portions of the deposited layer 20, and including at least the edge portion, are removed by a subsequent conventional wet etch process. Here, the exposed non-uniform region 20b of the deposited layer 20 at the edge of the wafer 10 corresponds to the dead zone region 24 described above with reference to FIG. 2. This exposed non-uniform region 20b is thus removed prior to performing the CMP planarization process. As a result, only a deposit layer pattern 40 (corresponding to all or a portion of the uniform region 20a) remains on the upper surface of the wafer 10. Here, a target thickness of the deposit layer removed by the wet etch process is in a range of approximately 5000-15000 Å.

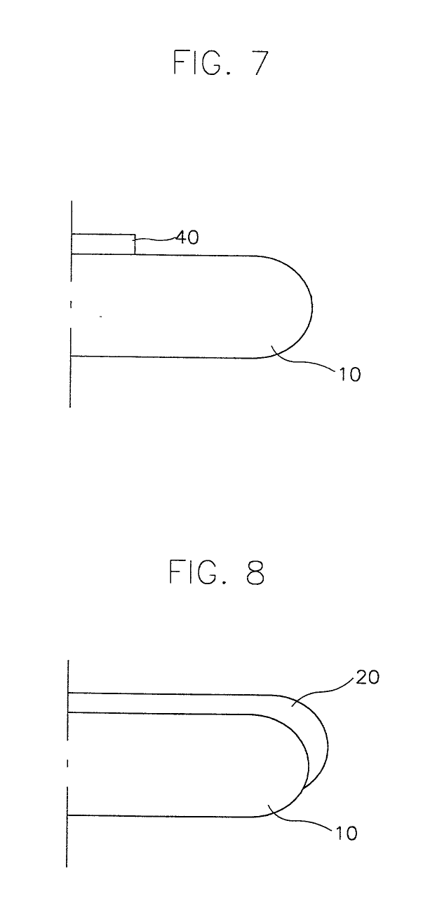

Referring to FIG. 7, the remaining photoresist film 30 is then stripped, leaving only the deposit layer pattern 40 remaining on the wafer 10. Thereafter, a CMP planarization process is performed to planarize the deposit layer pattern 40.

FIGS. 8 to 11 are schematic views illustrating a method for fabricating a semiconductor device in accordance with another embodiment of the present invention, in which the deposited layer at the upper sidewall region is removed after performing the CMP planarization process.

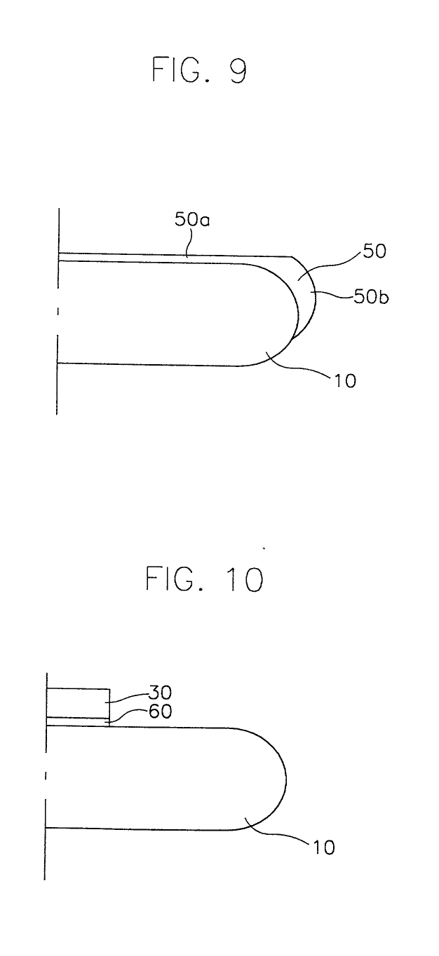

Referring to FIG. 8, a deposited layer 20 is formed on a wafer 10. Thereafter, the deposited layer 20 is planarized and polished using a CMP process, thereby forming a planarized layer 50 as shown in FIG. 9. Note that the planarized layer 50 has a region of uniform thickness 50a extending along the wafer surface and nearly to the edge of the wafer 10, and a region 50b of non-uniform thickness corresponding to an upper sidewall or edge of the wafer 10. In the planarized layer 50, the uniform region 50a is thinner than the non-uniform region 50b.

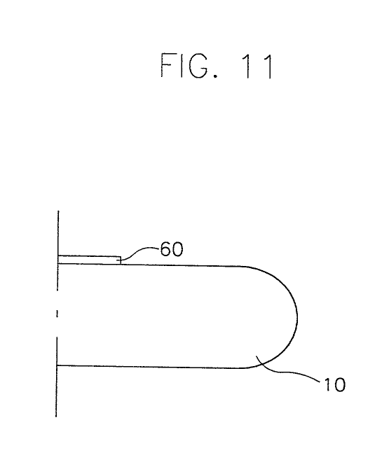

Referring to FIG. 10, a photoresist film 30 is then coated on the entire planarized layer 50 with a thickness in the range of approximately 5000-15000 Å. Afterwards, an edge portion of the photoresist film 30 removed by an edge expose wafer (EEW) process. to thereby expose at least the edge portion of the planarized layer 50 (i.e., non-uniform region 50b). Depending on the desired pattern, a portion of the uniform region 50a may also be exposed when the photoresist film 30 is removed.

Any exposed portions of the planarized layer 50, and including at least the edge portion, are removed by a subsequent conventional wet etch process. Here, the exposed non-uniform region 50b of the planarized layer 50 at the edge of the wafer 10 corresponds to the dead zone region 24 described above with reference to FIG. 2. This exposed non-uniform region 50b is thus removed after performing the CMP planarization process. Here, a target thickness of the planarized layer removed by the wet etch process is in a range of approximately 5000-15000 Å.

Referring to FIG. 11, the photoresist film 30 is then stripped away, leaving only the deposited layer pattern 60 (corresponding to all or a portion of the uniform region 50a) remaining on the upper surface of the wafer 10.

According to the above-described preferred embodiments, since a thick residual of the deposited layer formed on the sidewall of the wafer 10 is eliminated either before or after the CMP planarization process is completed, it is possible to prevent the generation of contaminating particles during subsequent manufacturing processes.

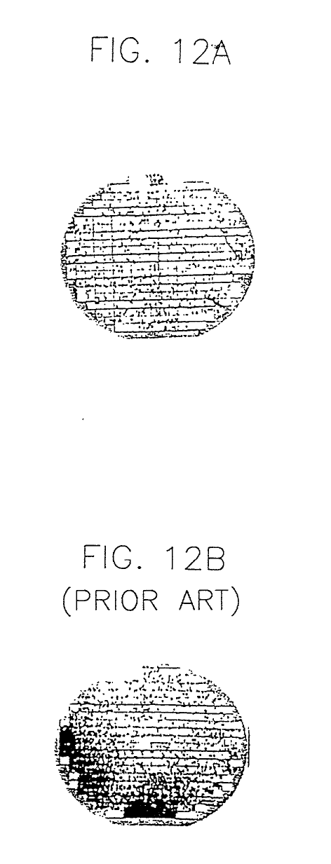

FIGS. 12A and 12B are particle maps-showing a distribution of particles after a subsequent process is performed on the wafer, comparing the conventional art process (FIG. 12B) in which particles are not removed prior to performing the subsequent process, and the present invention (FIG. 12A) in which particles are removed prior to performing the subsequent process.

As seen from FIGS. 12A and 12B, the wafer of the present invention in FIG. 12A exhibits remarkably fewer particles compared with the wafer of the conventional art as shown in FIG. 12B. This confirms that with the present inventive method, the number of particles introduced into the deposit layer pattern remarkably decreases due to the removal of the deposited (or planarized) layer portion of the dead zone region of the wafer, either prior to or after the CMP planarization process.

As a result, particle generation remarkably decreases and it thus becomes possible to secure high production yields and enhance the performance of the resulting devices.

While the present invention has been described in detail, it should be understood that various changes, substitutions and alterations could be made hereto without departing from the spirit and scope of the invention as defined by the appended claims.

What is claimed is:

1. A method of fabricating a semiconductor device, the method comprising:
depositing a layer to a predetermined thickness on a wafer;
planarizing the deposited layer to remove a portion of the deposited layer, the resulting planarized layer comprising a uniform region of uniform thickness extending along a wafer surface and nearly to an edge of the wafer, and a non-uniform region of non-uniform thickness corresponding to the edge of the wafer;
coating a photoresist layer on the planarized layer;
removing a portion of the coated photoresist layer corresponding to an edge region of the wafer, thereby exposing at least the non-uniform region of the planarized layer;
etching at least the exposed non-uniform region of the planarized layer; and
stripping a remaining portion of the coated photoresist layer on the planarized layer, thereby forming a pattern layer comprising a portion of the uniform region of the planarized layer.

2. The method of claim 1, wherein the planarizing comprises a chemical mechanical polishing (CMP) process.

3. The method of claim 1, wherein the coating of the photoresist layer continues until the photoresist layer has a thickness of approximately 5000-15000 Å.

4. The method of claim 1, wherein the etching comprises a wet etching process.

5. The method of claim 4, wherein the exposing also exposes a portion of the uniform region of the planarized layer.

6. The method of claim 5, wherein the wet etching also removes the exposed portion of the uniform region of the planarized layer.

7. A method of fabricating a semiconductor device, the method comprising:
depositing a layer to a predetermined thickness on a wafer, the deposited layer comprising a uniform region of uniform thickness extending along a wafer surface and nearly to an edge of the wafer, and a non-uniform region of non-uniform thickness corresponding to the edge of the wafer;
coating a photoresist layer on the deposited layer;
removing a portion of the coated photoresist layer corresponding to an edge region of the wafer, thereby exposing at least the non-uniform region of the deposited layer;
etching at least the exposed non-uniform region of the deposited layer;
stripping a remaining portion of the coated photoresist layer on the deposited layer; and
planarizing the uniform region of the deposited layer to thereby forming a pattern layer comprising the uniform region of the planarized layer.

8. The method of claim 7, wherein the planarizing comprises a chemical mechanical polishing (CMP) process.

9. The method of claim 7, wherein the coating of the photoresist layer continues until the photoresist layer has a thickness of approximately 5000-15000 Å.

10. The method of claim 7, wherein the etching comprises a wet etching process.

11. The method of claim 10, wherein the exposing also exposes a portion of the uniform region of the deposited layer.

12. The method of claim 11, wherein the wet etching also removes the exposed portion of the uniform region of the deposited layer.
